(19) United States
(12) Patent Application Publication
(10) Pub. No.: US 2018/0210069 A1
(43) Pub. Date: Jul. 26, 2018

(54) DISTANCE MEASURING DEVICE

(71) Applicant: HAMAMATSU PHOTONICS K.K., Hamamatsu-shi, Shizuoka (JP)

(72) Inventors: Mitsuhito MASE, Hamamatsu-shi (JP); Shinya IWASHINA, Hamamatsu-shi (JP); Takashi SUZUKI, Hamamatsu-shi (JP)

(73) Assignee: HAMAMATSU PHOTONICS K.K., Hamamatsu-shi, Shizuoka (JP)

(21) Appl. No.: 15/749,516

(22) PCT Filed: Jun. 21, 2016
(86) PCT No.: PCT/JP2016/068398

§ 371 Date: Feb. 1, 2018

(30) Foreign Application Priority Data
Oct. 16, 2015 (JP) 2015-204658

(51) Int. Cl. G01S 7/486; G01S 17/10; H01L 31/107; H01L 31/167

(52) U.S. Cl. CPC G01S 7/486; G01S 17/10; G01S 17/936; H01L 31/167; H01L 31/107

(57) ABSTRACT

A distance measuring device is configured to measure a distance to an object. The distance measuring device includes a light source configured to emit a projection beam to the object and a light receiving element configured to detect return light of the projection beam that is reflected by the object. The light source is a laser light source configured to emit pulsed light in an ultraviolet range to a blue color range as the projection beam, and the light receiving element is an avalanche photodiode that has spectral sensitivity in an ultraviolet range to a blue color range and operates in a Geiger mode.

### TECHNICAL FIELD

The present invention relates to a distance measuring device.

### BACKGROUND ART

Currently, the development of a distance measuring device using a time of flight (TOF) scheme in which light such as laser light is projected to an object, return light from the object is then detected, and a distance to the object is measured on the basis of a time from when light is projected to the object until return light is detected is progressing. It is assumed that such a distance measuring device would be mounted, for example, as an automatic driving support system in a vehicle such as an automobile. In an automatic driving support system, a distance between a vehicle that travels and an object (including a human body) is measured by the distance measuring device. Collision between the vehicle and the object can be expected to be avoided when a vehicle speed is controlled on the basis of the measurement result.

As a distance measuring device in the related art, for example, there is a radar device described in Patent Literature 1. The radar device includes a light source, a diode, and alight detection control unit. As a diode configured to detect return light from an object, a single photon avalanche diode (SPAD) is used. The light detection unit operates the SPAD after a timing at which scattered light inside the device due to light emitted from the light source enters the SPAD, and thus eliminates an influence of the scattered light.

### CITATION LIST

### Patent Literature

[Patent Literature 1] Japanese Unexamined Patent Publication No. 2015-117970

### SUMMARY OF INVENTION

### Technical Problem

In the radar device of Patent Literature 1, the SPAD having a higher light receiving sensitivity than a general photo diode (PD) and avalanche photo diode (APD) is used as a light receiving element. However, in a distance measuring device for a vehicle, when a projection beam emitted to an object and return light from an object are propagated in an external space, ambient light such as sunlight is assumed to be included. When an amount of ambient light increases, the S/N ratio of a signal decreases, and as a result, a measurable distance and distance measurement accuracy may not be sufficiently high.

In addition, in a distance measuring device for a vehicle, it is necessary to consider points at which a projection beam and return light are propagated in an external space. For example, since a projection beam and return light are propagated in a space in which pedestrians and the like travel, it is necessary to devise a method of reducing an influence of the projection beam and return light on a human body. Further, in order to maintain a measurable distance and distance measurement accuracy even in rainy weather, it is also necessary to examine light absorption characteristics of the projection beam and return light for water.

The present invention has been made in order to solve the above problems, and an object to the present invention is to provide a distance measuring device in which a measurable distance and distance measurement accuracy are able to be approved and which is appropriate for a vehicle.

### Solution to Problem

A distance measuring device according to an aspect of the present invention is configured to measure a distance to an object. The distance measuring device includes a light source configured to emit a projection beam to the object; and a light receiving element configured to detect a return light of the projection beam that is reflected by the object. The light source is a laser light source configured to emit pulsed light in an ultraviolet range to a blue color range as the projection beam, and the light receiving element is an avalanche photodiode that has spectral sensitivity in an ultraviolet range to a blue color range and operates in a Geiger mode.

The energy of ambient light such as sunlight tends to be higher on the longer wavelength side of a blue color range and lower on the shorter wavelength side of a blue color range within a visible light range. Therefore, when a light receiving element having spectral sensitivity in an ultraviolet range to a blue color range is used, it is possible to reduce an influence of ambient light when return light from the object is detected. When an influence of ambient light is reduced and return light is detected in an avalanche photodiode that operates in a Geiger mode, it is possible to ensure a sufficient S/N ratio for a signal, and increase a measurable distance and distance measurement accuracy. In addition, for light in an ultraviolet range to a blue color range, an absorption coefficient of water is smaller than that for light in the visible light range on a longer wavelength side of a blue color range, and a maximum permissible exposure for the retina of the human body is higher than that for light in the visible light range on a longer wavelength side of a blue color range. Therefore, when a laser light source configured to emit pulsed light in an ultraviolet range to a blue color range is used, it is possible to reduce an influence on the human body and deterioration in distance measurement performance due to rainy weather.

The light source may be a laser light source configured to emit pulsed light of 300 nm to 400 nm as a projection beam. When light in this wavelength range is used as the light source, it is possible to optimize conditions including an absorption coefficient of water and a maximum permissible exposure for the retina of the human body.

In addition, the light receiving element may be a silicon photomultiplier tube. A silicon photomultiplier tube has excellent spectral sensitivity in an ultraviolet range to a blue color range and functions suitably as an avalanche photodiode that operates in a Geiger mode.

### Advantageous Effects of Invention

In the distance measuring device, it is possible to increase a measurable distance and distance measurement accuracy, and the device is appropriate for a vehicle.

### BRIEF DESCRIPTION OF DRAWINGS

FIG. 1 is a diagram showing an embodiment of a distance measuring device.

FIG. 2 is a perspective view showing an example of a configuration of a light receiving element.

FIG. 3 is a sectional view taken along the III-III in FIG. 2.

FIG. 4 is a graph showing spectral sensitivity characteristics of an MPPC.

FIG. 5 is a graph showing an influence of ambient light.

FIG. 6 is a graph showing a maximum permissible exposure for the retina of the human body.

FIG. 7 is a graph showing light absorption characteristics for water.

FIG. 8 is a diagram showing an appropriate wavelength range used in a distance measuring device.

### DESCRIPTION OF EMBODIMENTS

Exemplary embodiments of a distance measuring device according to an aspect of the present invention will be described below in detail with reference to the drawings.

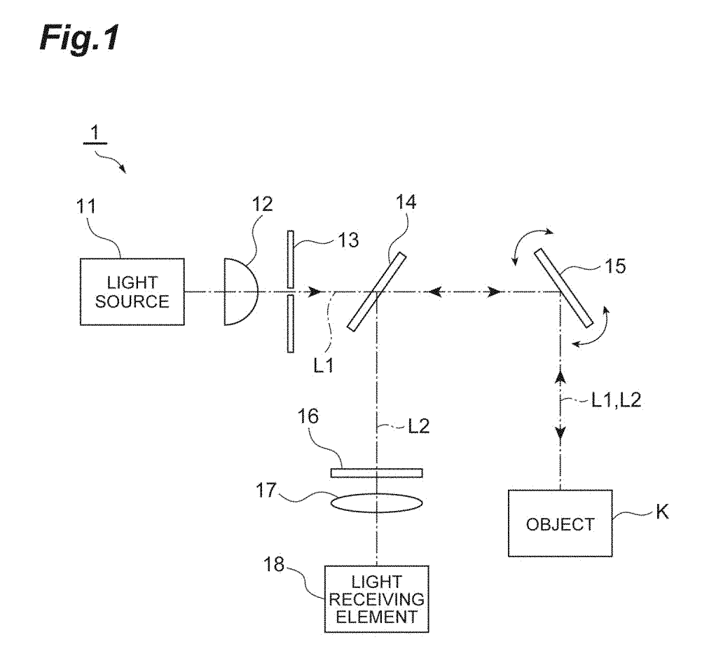

FIG. 1 is a perspective view showing an embodiment of a distance measuring device. A distance measuring device 1 is a device that is mounted, for example, as an automatic driving support system in a vehicle such as an automobile. In the automatic driving support system, a distance between a vehicle that travels and an object K is measured in real time by the distance measuring device 1, a vehicle speed is controlled on the basis of the measurement result, and control for avoiding collision between the vehicle and the object K is performed. The object K is, for example, another vehicle, an obstacle such as a wall, or a pedestrian. In the present embodiment, for example, a distance from an object K positioned about 0.1 m to 100 m away is assumed to be measured.

As shown in FIG. 1, the distance measuring device 1 includes a light source 11, a collimator 12, an aperture 13, a beam splitter 14, a scanning mirror 15, a wavelength selection filter 16, a condenser lens 17, and a light receiving element 18. These components are assembled on, for example, a substantially plate-like stage.

The light source 11 is a unit configured to emit a projection beam L1 to the object K. As the light source 11, a laser diode configured to emit pulsed light in an ultraviolet range to a blue color range is used. The wavelength of the projection beam L1 is, for example, 300 nm to 500 nm, preferably 300 nm to 400 nm, and more preferably 350 nm to 400 nm. The projection beam L1 emitted from the light source 11 is collimated by the collimator 12 and is guided to the beam splitter 14 while a beam diameter is reduced to, for example, φ10 mm or less, by the aperture 13.

The projection beam L1 that has passed through the beam splitter 14 is guided to the scanning mirror 15. The scanning mirror 15 is, for example, a microelectromechanical systems (MEMS) mirror. The scanning mirror 15 swings in an in-plane direction of a stage 9 on the basis of control by a control unit (not shown), and scans in the direction of the projection beam L1 toward the object K. The diameter of the mirror part of the scanning mirror 15 is, for example, approximately the same as the diameter of the projection beam L1. A swing angle of the scanning mirror 15 is, for example, about ±30°. In addition, a scanning speed of the scanning mirror 15 is, for example, about 0.1 kHz to 10 kHz.

In addition, the scanning mirror 15 reflects return light L2 obtained when the projection beam L1 is reflected by the object K toward the beam splitter 14. The return light L2 reflected by the beam splitter 14 passes through the wavelength selection filter 16, and is then condensed on a light receiving surface of the light receiving element 18 by the condenser lens 17. The wavelength selection filter 16 is a band pass filter through which light having a wavelength corresponding to spectral sensitivity characteristics of the light receiving element 18 is transmitted, and, for example, transmits light having a wavelength of 300 nm to 500 nm, but blocks light in other wavelength bands. A transmission band of the wavelength selection filter 16 may be appropriately set according to the wavelength of light emitted from the light source 11.

The light receiving element 18 is a unit configured to detect the return light L2 from the object K. As the light receiving element 18, an avalanche photodiode that operates in a Geiger mode is used. The Geiger mode is a mode in which an operation is performed at a reverse voltage of the avalanche photodiode that is set to a breakdown voltage or higher. In a high electric field in a Geiger mode, a discharge phenomenon (Geiger discharge) occurs even if weak light enters, and an electron multiplication constant is about 105 to 106.

As the avalanche photodiode that operates in a Geiger mode, for example, a single-photon avalanche diode (SPAD) and a multi-pixel photon counter/silicon photomultiplier tube (MPPC) may be exemplified. For example, in the MPPC, pixels of the avalanche photodiode that operates in a Geiger mode are two-dimensionally connected in parallel. A quenching resistor is connected to each pixel, and each quenching resistor is connected to one readout channel. Therefore, when a height (event number) of a pulse or a charge amount of a pulse on which signals from pixels are superimposed is measured, it is possible to detect the number of photons detected by the MPPC.

An output signal from the light receiving element 18 is output to a calculation unit (not shown). In the calculation unit, a distance to the object K is calculated on the basis of a time of light (TOF) scheme. That is, the calculation unit calculates a distance to the object K on the basis of a difference between a time point at which a pulse of the projection beam L1 is emitted from the light source 11 and a time point at which the return light L2 is detected by the light receiving element 18.

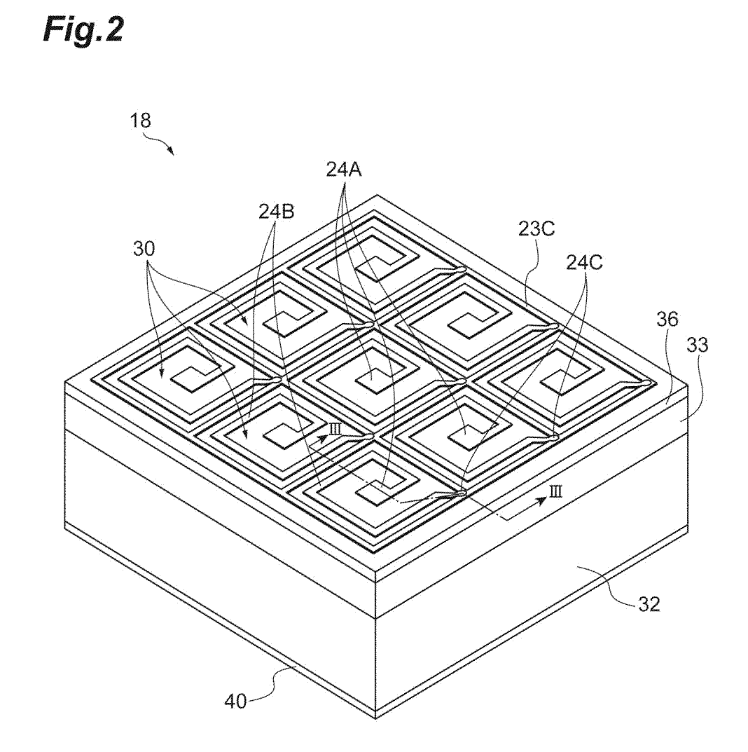

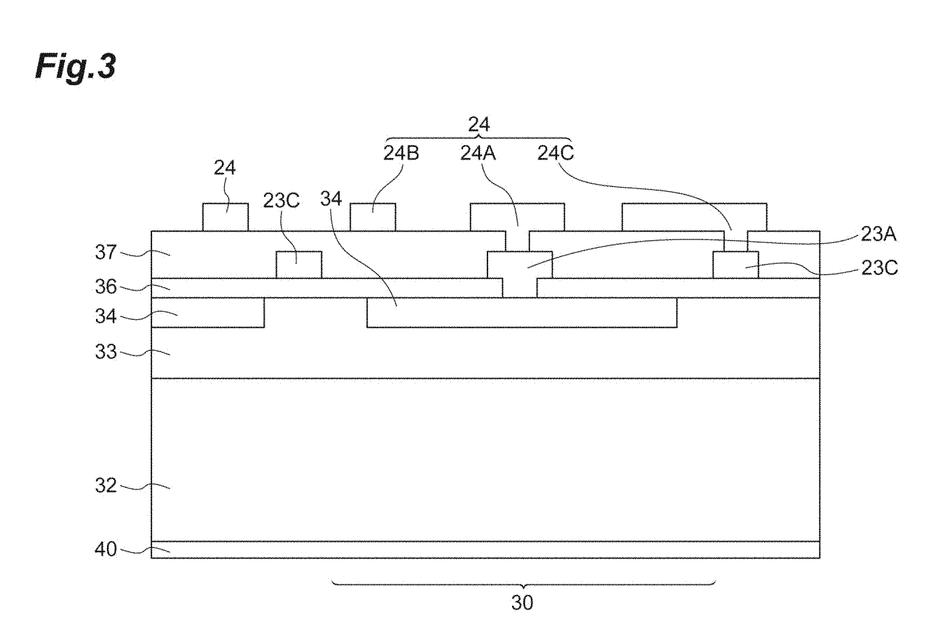

FIG. 2 is a perspective view showing an example of a configuration of the light receiving element. In addition, FIG. 3 is a sectional view taken along the III-III in FIG. 2. FIG. 2 and FIG. 3 exemplify a configuration of the MPPC. In addition, in FIG. 2, an insulating layer 37 shown in FIG. 3 is omitted for convenience of illustration.

As shown in FIG. 2 and FIG. 3, the MPPC which is the light receiving element 18 includes a light receiving area on one surface side of a semiconductor substrate made of Si. The light receiving area includes, for example, a plurality of light detection units 30 that are two-dimensionally arranged in a matrix form. A wiring pattern 23C for signal reading patterned in a lattice form is arranged on a front surface side of the substrate. The inside of an opening of the lattice wiring pattern 23C defines a light detection area. The light detection units 30 arranged in the light detection area are connected to the wiring pattern 23C.

A bottom electrode 40 is provided on a back surface side of the substrate. When a drive voltage of the light detection unit 30 is applied between the wiring pattern 23C that is a top electrode and the bottom electrode 40, an output signal from the light detection unit 30 can be extracted from the wiring pattern 23C.

A pn junction consists of a p-type semiconductor area that constitutes an anode and an n-type semiconductor area that constitutes a cathode. When a drive voltage is applied to a photodiode so that a potential of the p-type semiconductor area is higher than a potential of the n-type semiconductor area, this is a forward bias voltage. When a drive voltage reverse thereto is applied to a photodiode, this is a reverse bias voltage.

The drive voltage is a reverse bias voltage that is applied to a photodiode constituted by an internal pn junction in the light detection unit 30. When the drive voltage is set to a breakdown voltage of the photodiode or higher, avalanche breakdown occurs in the photodiode, and the photodiode operates in a Geiger mode. Here, even if a forward bias voltage is applied to the photodiode, a light detection function of the photodiode is exhibited.

A resistor unit (quenching resistor) 24 electrically connected to one end of the photodiode is arranged on a front surface side of the substrate. One end of the resistor unit 24 constitutes a contact electrode 24A electrically connected to one end of the photodiode through a contact electrode made of another material which is positioned directly therebelow. The other end of the resistor unit 24 is in contact with the wiring pattern 23C for signal reading and constitutes a contact electrode 24C electrically connected thereto. That is, the resistor unit 24 in each of the light detection units 30 includes the contact electrode 24A connected to the photodiode, a resistance layer 24B that continuously extends in the contact electrode 24A in a curved manner and the contact electrode 24C that is continuous to a terminal end of the resistance layer 24B. Here, the contact electrode 24A, the resistance layer 24B, and the contact electrode 24C are constituted by a resistance layer made of the same resistance material.

One end of the photodiode included in the light detection unit 30 is connected to the wiring pattern 23C with the same potential at all positions in principle, and the other end thereof is connected to the bottom electrode 40 configured to apply a substrate potential. That is, photodiodes in all of the light detection units 30 are connected in parallel.

As shown in FIG. 2, the light detection units 30 each include an n-type first semiconductor layer 32, a p-type second semiconductor layer 33 constituting a pn junction with the first semiconductor layer 32, and a high impurity concentration area 34. A first contact electrode 3A is in contact with the high impurity concentration area 34. The high impurity concentration area 34 is a diffuse area that is formed by diffusing impurities into the second semiconductor layer 33, and has a higher impurity concentration than the second semiconductor layer 33.

In the present embodiment, the p-type second semiconductor layer 33 is formed on the n-type first semiconductor layer 32 and the p-type high impurity concentration area 34 is formed on the front surface side of the second semiconductor layer 33. Therefore, the pn junction constituting the photodiode is formed between the first semiconductor layer 32 and the second semiconductor layer 33. As a layer structure of the semiconductor substrate, a structure having a conductivity type that is inverted from that of the above structure can be used. In this case, the n-type second semiconductor layer 33 is formed on the p-type first semiconductor layer 32, and the n-type high impurity concentration area 34 is formed on the front surface side of the second semiconductor layer 33.

In addition, a pn junction interface can be formed on the surface layer side. In this case, a structure in which the n-type second semiconductor layer 33 is formed on the n-type first semiconductor layer 32 and the p-type high impurity concentration area 34 is formed on the front surface side of the second semiconductor layer 33 is formed. In this structure, the pn junction is formed at an interface between the second semiconductor layer 33 and the high impurity concentration area 34. In such a structure, the conductivity type can be inverted.

The light detection units 30 each include an insulating layer 36 formed on the surface of the semiconductor substrate. The surfaces of the second semiconductor layer 33 and the high impurity concentration area 34 are covered by the insulating layer 36. The insulating layer 36 has a contact hole, and a contact electrode 23A is formed in the contact hole. The upper insulating layer 37 is formed on the insulating layer 36 and the contact electrode 23A. The insulating layer 37 has a contact hole arranged coaxially with the contact electrode 23A, and the contact electrode 24A is formed in the contact hole.

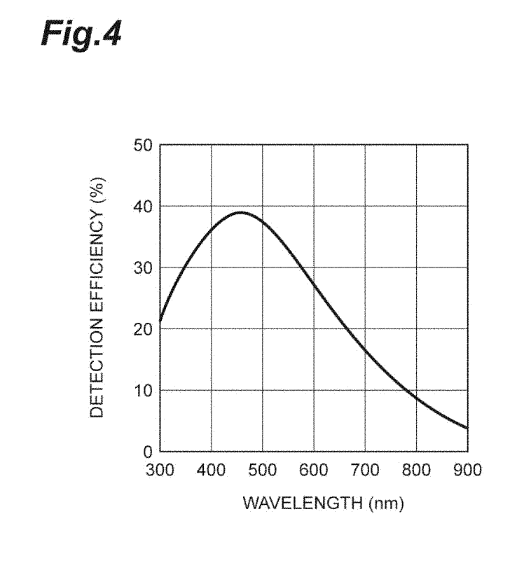

FIG. 4 is a graph showing spectral sensitivity characteristics of the MPPC described above. In FIG. 4, the horizontal axis represents a wavelength, and the vertical axis represents photon detection efficiency. In addition, the spectral sensitivity characteristics are obtained when an MPPC which has 400 light detection units and an arrangement pitch of the light detection units that is 25 μm operates in a Geiger mode at a reverse bias voltage of 74 V. Here, a breakdown voltage of the MPPC is 71 V.

As shown in FIG. 4, the photon detection efficiency in the MPPC has a peak near a wavelength of 450 nm. The photon detection efficiency at a peak wavelength is about 38%. The photon detection efficiency in the MPPC is about 22% to 38% in a wavelength range of 300 nm to 500 nm, about 22% to 35% in a wavelength range of 300 nm to 400 nm, and about 29% to 35% in a wavelength range of 350 nm to 400 nm.

On the other hand, the photon detection efficiency in the MPPC is about 28% at a wavelength of 600 nm, about 17% at a wavelength of 700 nm, and about 9% at a wavelength of 800 nm, and gradually decreases on a longer wavelength side of a blue color range. Therefore, the above-described MPPC is a light receiving element having high spectral sensitivity in an ultraviolet range to a blue color range. The reason why the MPPC has high spectral sensitivity in an ultraviolet range to a blue color range can be inferred to be due to a structure in which an absorption length of short wavelength light incident on the light receiving surface of the MPPC matches the position of the avalanche layer, and electrons having a high ionization rate are injected into the avalanche layer. In addition, since a high electric field in a Geiger mode is applied, there is a high probability of an electric charge being accelerated by the electric field before it is absorbed into the semiconductor layer.

Next, operations and effects of the distance measuring device 1 described above will be described.

As described above, in the distance measuring device 1, the avalanche photodiode that operates in a Geiger mode is used as the light receiving element 18. The light receiving element 18 has a higher light receiving sensitivity than a general photo diode (PD) or avalanche photo diode (APD), but it is easily influenced by ambient light such as sunlight.

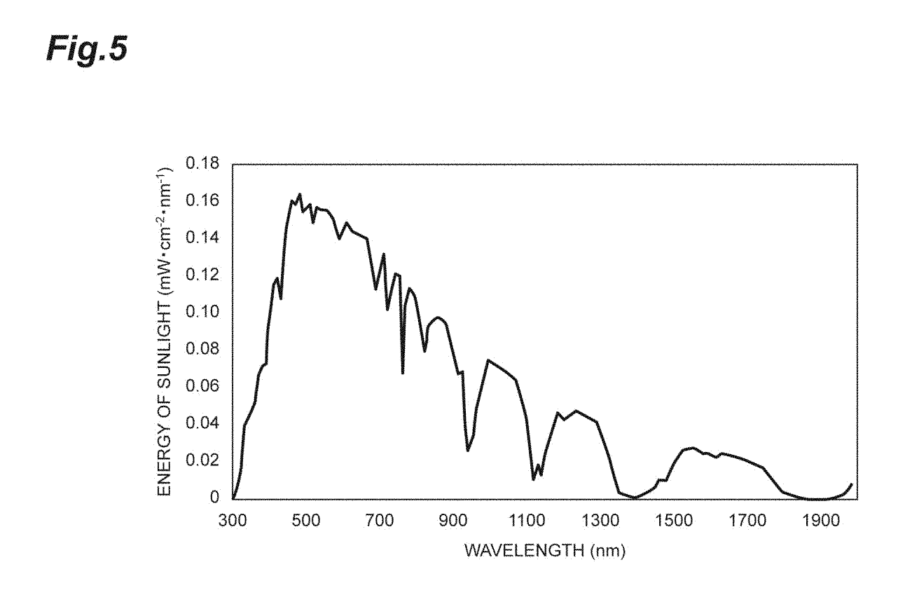

Here, FIG. 5 is a graph showing the influence of ambient light. In FIG. 5, sunlight is exemplified as a main component of ambient light, and the horizontal axis represents a wavelength, and the vertical axis represents an energy of sunlight during daytime near the ground surface. As shown in FIG. 5, the energy of sunlight has a peak wavelength near 500 nm. On a shorter wavelength side and a longer wavelength side of this peak, while the energy of the sunlight decreases moving away from the peak wavelength, a rate of decrease thereof is much larger on the shorter wavelength side than on the longer wavelength side.

Based on this result, it can be understood that, in the visible light range, the energy of ambient light tends to be higher on the longer wavelength side of a blue color range and lower on the shorter wavelength side of a blue color range. Therefore, when the light receiving element 18 having spectral sensitivity in an ultraviolet range to a blue color range is used, it is possible to reduce an influence of ambient light when the return light L2 from the object K is detected. When an influence of ambient light is reduced and return light is detected in the avalanche photodiode that operates in a Geiger mode, it is possible to ensure a sufficient S/N ratio of a signal, and increase a measurable distance and distance measurement accuracy. In addition, when a wavelength range in which the energy of ambient light is small is selected, even if a power of the projection beam L1 emitted from the light source 11 is reduced, it is possible to ensure the sufficient S/N ratio of the signal. Therefore, it is possible to reduce power consumption of the distance measuring device 1.

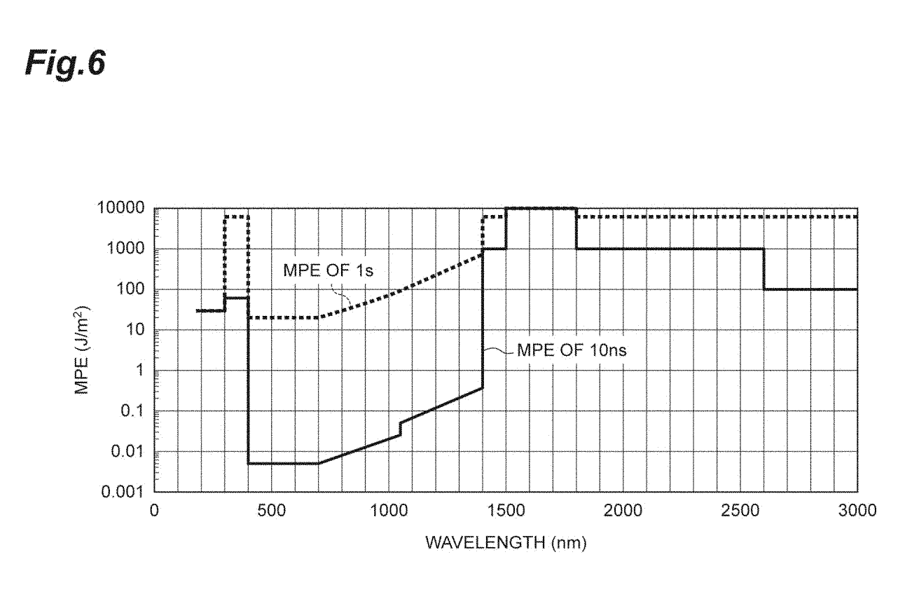

In addition, FIG. 6 is a graph showing a maximum permissible exposure for the retina of the human body. In FIG. 6, the horizontal axis represents a wavelength, and the vertical axis represents a maximum permissible exposure (MPE) for the retina. In addition, in FIG. 6, a maximum permissible exposure of 10 ns is indicated by a solid line, and a maximum permissible exposure of 1 s is indicated by a dashed line. The maximum permissible exposure of 10 ns is a maximum permissible exposure when an incident time of one pulse of laser light is 10 ns, and the maximum permissible exposure of 1 s is a maximum permissible exposure when an incident time of one pulse of laser light is 1 s.

In general, damage to the retina of the human body due to laser light depends on a wavelength, an exposure time, and a condensing diameter of laser light incident on the retina. The maximum permissible exposure is defined as a laser light intensity of 1/10 of a level at which a fault occurrence rate due to laser emission is 50% in the laser safety standard (JIS C 6802).

As shown in FIG. 6, in both the MPE of 10 ns and the MPE of 1 s, the MPE in a near infrared range is higher than the MPE in a visible light range. The MPE of 10 ns in the visible light range is on the order of 0.01 J/cm² to 0.1 J/cm², and the MPE of 10 ns in the visible light range is on the order of 100 J/cm² to 10,000 J/cm². On the other hand, the MPE of 1 s in a wavelength band of 1,400 nm or higher is on the order of 10 J/cm² to 10,000 J/cm², and the MPE of 1 s in the same band is approximately on the order of 10,000 J/cm².

In addition, in both the MPE of 10 ns and the MPE of 1 s, the MPE in an ultraviolet range is higher than the MPE in a visible light range. The MPE of 10 ns in a band of a wavelength of 400 nm or less is on the order of 10 J/cm² to 100 J/cm² and the MPE of 1 s in the same band is on the order of 10 J/cm² to 10,000 J/cm².

Based on the above-described results, when a laser light source configured to emit pulsed light in an ultraviolet range to a blue color range is used as the light source 11, it is possible to ensure being sufficiently within a maximum permissible exposure for the retina of the human body with respect to the projection beam L1 and the return light L2. In the distance measuring device 1 for a vehicle as in the present embodiment, the projection beam L1 and the return light L2 are propagated in an external space from the distance measuring device 1 to the object K. Since this external space is a space traveled in which pedestrians and the like travel, the projection beam L1 and the return light L2 are considered to be emitted to the human body. Therefore, when wavelengths of the projection beam L1 and the return light L2 are selected and being within the maximum permissible exposure is ensured, it is possible to realize safety for the retina of the human body (eye safety).

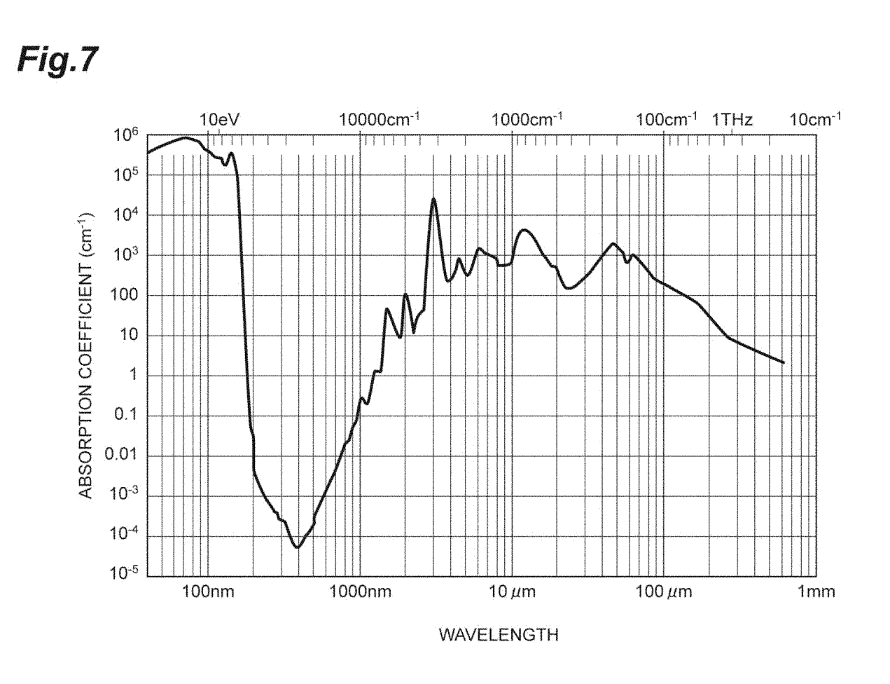

FIG. 7 is a graph showing light absorption characteristics for water. In FIG. 7, the horizontal axis represents a wavelength, and the vertical axis represents an absorption coefficient. As shown in FIG. 7, an absorption coefficient of water is the smallest at near a wavelength of 400 nm, which is 10⁻⁴ cm⁻¹ or less. Even in a range near a wavelength of 400 nm, the absorption coefficient of water is smaller than in other wavelength ranges, and is 10⁻⁴ cm⁻¹ or less in a wavelength range of 300 nm to 500 nm.

Based on the above-described results, when a laser light source configured to emit pulsed light in an ultraviolet range to a blue color range is used as the light source 11, it is possible to reduce an influence of absorption of water on the projection beam L1 and the return light L2. In the distance measuring device 1 for a vehicle as in the present embodiment, the projection beam L1 and the return light L2 are propagated in an external space from the distance measuring device 1 to the object K. When the projection beam L1 and the return light L2 are propagated in the external space, depending on the weather, the projection beam L1 and the return light L2 are assumed to pass through raindrops, mist, and the like. Therefore, when wavelengths of the projection beam L and the return light L2 are selected so that an influence of absorption of water is reduced, it is possible to ensure a measurable distance and distance measurement accuracy independently of the weather.

As described above, in the distance measuring device 1, the laser light source configured to emit pulsed light in an ultraviolet range to a blue color range as the projection beam L1 is used as the light source, and the avalanche photodiode which has spectral sensitivity in an ultraviolet range to a blue color range and operates in a Geiger mode is used as the light receiving element 18. Accordingly, in the distance measuring device 1, it is possible to increase a measurable distance and distance measurement accuracy by eliminating an influence of ambient light, realize eye safety, and minimize fluctuation in the measurable distance and distance measurement accuracy by eliminating an influence of absorption of water.

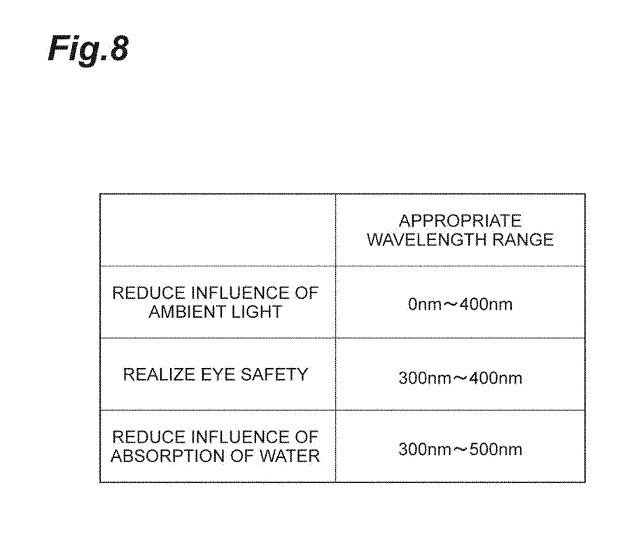

FIG. 8 is a diagram showing an appropriate wavelength range used in the distance measuring device. Referring to the graph shown in FIG. 5, a wavelength range appropriate for reducing an influence of ambient light is 300 nm to 400 nm. As shown in FIG. 4, the photon detection efficiency in the MPPC is about 22% to 35% in a wavelength range of 300 nm to 400 nm and sufficient detection efficiency is exhibited in this range.

Referring to the graph shown in FIG. 6, an appropriate wavelength range for realizing eye safety is 300 nm to 400 nm. In addition, referring to the graph shown in FIG. 7, a wavelength range appropriate for reducing an influence of absorption of water is 300 nm to 400 nm. Based on such results, when a laser light source configured to emit pulsed light of 300 nm to 400 nm as the projection beam L1 is used as the light source 11 and an MPPC (silicon photomultiplier tube) is used as the light receiving element 18, it is possible to exhibit the above effects more reliably.

Here, when a laser diode is used as the light source 11, care needs to be taken because a wavelength of laser light emitted from the laser diode depends on a temperature. In general, a dependence of a wavelength of a laser diode in an ultraviolet range on temperature is smaller by about one order of magnitude than a dependence of a wavelength of a laser diode in a near infrared range on temperature, and is, for example, 0.03 nm/° C. to 0.04 nm/° C. Therefore, even if a temperature range of an environment in which the distance measuring device 1 for a vehicle is used is assumed to be −40° C. to 105° C., an amount of a change in wavelength is several nm or less, and an influence of a dependence of a wavelength on temperature is extremely small.

In addition, in the present embodiment, as shown in FIG. 4, the photon detection efficiency in the MPPC has a peak near a wavelength of 450 nm. On the other hand, when a wavelength of laser light emitted from the light source 11 is 300 nm to 400 nm, a wavelength of a peak of detection efficiency of the MPPC is longer than a wavelength of the laser light. Therefore, even if a temperature of an environment in which the distance measuring device 1 is used shifts to a high temperature side, detection efficiency of the MPPC increases and it is possible to sufficiently ensure a measurable distance and distance measurement accuracy.

### REFERENCE SIGNS LIST

1 Distance measuring device
11 Light source
18 Light receiving element
K Object
L1 Projection beam
L2 Return light

1. A distance measuring device configured to measure a distance to an object, comprising:
a light source configured to emit a projection beam to the object; and
a light receiving element configured to detect a return light of the projection beam that is reflected by the object,
wherein the light source is a laser light source configured to emit pulsed light in an ultraviolet range to a blue color range as the projection beam, and
wherein the light receiving element is an avalanche photodiode that has spectral sensitivity in an ultraviolet range to a blue color range and operates in a Geiger mode.

2. The distance measuring device according to claim 1,
wherein the light source is a laser light source configured to emit pulsed light of 300 nm to 400 nm as the projection beam.

3. The distance measuring device according to claim 1,
wherein the light receiving element is a silicon photomultiplier tube.
